(19) United States
(12) Patent Application Publication
(10) Pub. No.: US 2025/0118541 A1
(43) Pub. Date: Apr. 10, 2025

(54) PLASMA PROCESSING APPARATUS

(71) Applicant: Hitachi High-Tech Corporation, Minato-ku, Tokyo (JP)

(72) Inventors: Tomoaki HYODO, Tokyo (JP); Shintaro NAKATANI, Tokyo (JP); Takamasa ICHINO, Tokyo (JP); Yuki TANAKA, Tokyo (JP)

(21) Appl. No.: 18/280,374

(22) PCT Filed: Jun. 23, 2022
(86) PCT No.: PCT/JP2022/025026

§ 371 Date: Sep. 5, 2023

(51) Int. Cl. H01J 37/32; H01L 21/67; H05B 6/62

(52) U.S. Cl. CPC H01J 37/32724; H01L 21/67103; H01L 21/67248; H05B 6/62; H01J 2237/334

(57) ABSTRACT

A plasma processing apparatus for manufacturing multi-zone heater layer electrodes including a first heater layer disposed in a dielectric film covering an upper surface of a sample table, the first heater layer including a plurality of film-shaped heaters each having a rectangular shape; and a plurality of temperature sensors disposed below the rectangular regions of the first heater layer and corresponding to circuit patterns of a plurality of semiconductor devices formed on an upper surface of a wafer, and include four regions each having one side facing an adjacent region, and with the film-shaped heaters disposed in the four regions being one set including four power supply paths and one return path, the four power supply paths being electrically each connected to one place of each of the film-shaped heaters of the set, and the one return path being electrically connected to another place of each of the film-shaped.

### TECHNICAL FIELD

The present disclosure relates to a plasma processing apparatus in which a substrate-shaped sample such as a semiconductor wafer is disposed on an upper surface of a sample table in a processing chamber in a vacuum container, and the sample is processed using plasma formed by supplying a processing gas in the processing chamber, and particularly to a plasma processing apparatus in which a plurality of film-shaped heaters are provided in a dielectric film that Covers the upper surface of the sample table, and the sample is processed while adjusting a temperature of the sample by the heaters.

### BACKGROUND ART

In the plasma processing apparatus, in order to shorten a time for etching a so-called multi-layer film in which a plurality of films formed on a surface of a plate-shaped sample such as a semiconductor wafer (hereinafter, also simply referred to as a wafer) are stacked, the films adjacent to one another in an upper-lower direction are processed in the same processing chamber without taking the wafer out of the processing chamber during processing of the films.

In such processing, it is important to adjust a temperature of the sample table disposed in the processing chamber to a suitable temperature to process the wafer. Therefore, the heaters are built in the sample table of the plasma processing apparatus, and when processing the wafer, the temperature is adjusted to a temperature suitable for processing, and processing accuracy is improved.

As an example of such a plasma processing apparatus, an invention disclosed in JP-A-2007-67036 (PTL 1) is already known. The present related art discloses a plasma processing apparatus in which inside a metal disk that constitutes a sample table disposed in a processing chamber in a vacuum container or a cylindrical base material, ring-shaped heater films are formed by thermal spray at refrigerant flow paths disposed concentrically in a multiply winding manner and allowing a refrigerant to flow through, and the metal disk or an upper portion of the cylindrical base material, and a temperature distribution in a wafer surface can be changed for each etching condition.

As another example of the related art of such a plasma processing apparatus, an invention disclosed in JP-A-2017-157855 (PTL 2) is known. The present related art discloses a plasma processing apparatus in which inside a metal disk that constitutes a sample table disposed in a processing chamber in a vacuum container or a cylindrical base material, a first heater element and a second heater element having a larger number of divisions and a smaller heat generation amount than those of the first heater element, which have concentric circular shapes, are disposed at refrigerant flow paths disposed concentrically in a multiply winding manner allowing a refrigerant to flow through, and a metal disk or an upper portion of a cylindrical base material. In the related art, the semiconductor wafer can be processed while controlling the temperature of the semiconductor wafer disposed on the sample table.

### CITATION LIST

### Patent Literature

PTL 1: JP2007-67036A
PTL 2: JP2017-157855A

### SUMMARY OF INVENTION

### Technical Problem

Consider a case in which, in the related art, multiple heaters are provided to control a temperature of the electrodes. In this case, the following problem occurs, A total of two holes are necessary for each zone, one for power supply and one for current return, and hole disposition becomes more difficult as the number of zones increases. Further, even if disposed, drilling a large number of holes is expensive and difficult to process.

The present disclosure provides safe, low-cost, and easy-to-manufacture techniques for multi-zone heater layer (heater wire) electrodes.

### Solution to Problem

A plasma processing apparatus according to one aspect of the present disclosure includes:
a processing chamber disposed in a vacuum container and configured to allow a wafer to be processed to be disposed and allow plasma to be formed in the processing chamber;
a cylindrical sample table disposed in the processing chamber, the sample table having an upper surface configured to allow the wafer to be placed;
a first heater layer disposed in a dielectric film covering an upper surface of a disk-shaped base material of the sample table, the first heater layer including a plurality of film-shaped heaters respectively disposed in a plurality of regions having a rectangular shape; and
a plurality of temperature sensors disposed in the base material below the rectangular regions of the first heater layer, in which
the plurality of regions are disposed corresponding to circuit patterns of a plurality of semiconductor devices formed on an upper surface of the wafer, and include four regions in which each of the plurality of regions has one side of the rectangle facing an adjacent region, and
with the film-shaped heaters disposed in the four regions being one set, each set includes four power supply paths and one return path, the four power supply paths being electrically each connected to one place of each of the film-shaped heaters of the set and being configured to supply power from a direct-current power supply, the one return path being electrically connected to another place of each of the film-shaped heaters and being configured to allow the power to return to the direct-current power supply.

That is, a method for collecting the return current to the base material is adopted. Specifically, via processing is performed on the base material, and the heater layer and the base material are connected by Tungsten via wiring, so that the return current of the heater can be collected on the base material.

### Advantageous Effects of Invention

According to the plasma processing apparatus according to one aspect of the present disclosure, multi-zone heater layer (heater wire) electrodes can be manufactured safely, inexpensively, and easily.

### BRIEF DESCRIPTION OF DRAWINGS

FIG. 1 is a longitudinal cross-sectional view schematically showing a configuration of a plasma processing apparatus according to an embodiment.

FIG. 2 is a cross-sectional view schematically showing a part of a configuration of a sample table of the plasma processing apparatus shown in FIG. 1.

FIG. 3 is a partially enlarged cross-sectional view schematically showing a part of the configuration of the sample table of the plasma processing apparatus shown in FIG. 2.

FIG. 4 is a diagram showing an example of a second heater in the sample table,

FIG. 5 is a diagram showing an example of a first heater in the sample table.

FIG. 6 is a disposition diagram of power supply portions and a return portion of grid heaters.

FIG. 7 is an enlarged view of a set of four grid heaters.

FIG. 8 is a diagram of the four grid heaters and an example of polarity reversion in power supply portions thereof.

FIG. 9 is a schematic diagram showing a relationship between four corners (a first corner cha, a second corner cnb, a third corner cnc, and a fourth corner cnd) as well as four sides (a first side SL1, a second side SL2, a third side SL3, and a fourth side SL4) of a rectangular region 501 described in FIG. 5 and four regions in FIG. 7 (a first region CH1, a second region CH2, a third region CH3, and a fourth region CH4).

### DESCRIPTION OF EMBODIMENTS

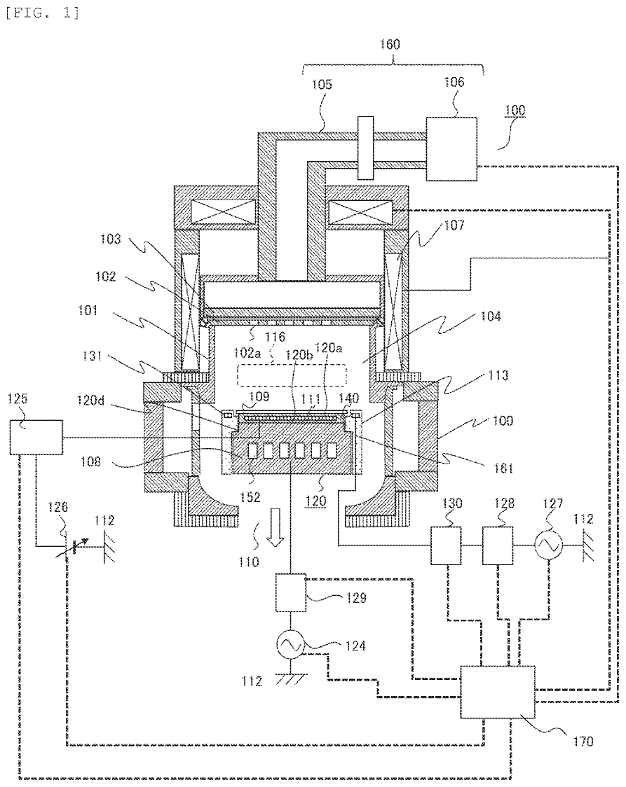

An embodiment of the present disclosure will be described with reference to the drawings. Hereinafter, an embodiment of the present disclosure will be described with reference to FIGS. 1 to 8. FIG. 1 is a cross-sectional view schematically showing a schematic configuration of a plasma processing apparatus according to the embodiment. Particularly, FIG. 1 shows a plasma etching apparatus that uses an electric field of a microwave as an electric field for forming a plasma to generate an electron cyclotron resonance (BCR) between the electric field of the microwave described above and a magnetic field and form a plasma, and that etches a substrate-shaped sample such as a semiconductor wafer by using the plasma described above. The plasma etching apparatus (plasma processing apparatus) 100 shown in FIG. 1 will be described. The plasma etching apparatus 100 includes a vacuum container 101 internally including a processing chamber 104 where the plasma is formed. In the vacuum container 101, an upper portion having a cylindrical shape is opened, a dielectric window 103 (for example, made of quartz) for introducing the microwave is disposed as a lid member on the upper portion, and the processing chamber 104 whose internal portion and external portion are hermetically partitioned is formed. Further, a vacuum exhaust port 110 is disposed in a lower portion of the vacuum container 101, and communicates with a vacuum exhaust apparatus (not shown) disposed below the vacuum container 101 and connected thereto. Further, a shower plate 102 that constitutes a ceiling surface of the processing chamber 104 is provided below a lower surface of the dielectric window 103 that constitutes the lid member of an upper portion of the vacuum container 101. The shower plate 102 includes a plurality of gas introduction holes 102a disposed in a central portion. Etching gas is introduced into the processing chamber 104 through the plurality of gas introduction holes 102a. The shower plate 102 is a disk made of a dielectric such as quartz.

Further, an electric field and magnetic field formation portion 160 that forms an electric field and a magnetic field for generating plasma 116 is disposed at a place outside and above the vacuum container 101. The electric field and magnetic field formation portion 160 includes the following configurations and is provided in the plasma etching apparatus 100. That is, the electric field and magnetic field formation portion 160 is provided with a waveguide 105 disposed above the dielectric window 103. The waveguide 105 allows the electric field to be transmitted through in order to supply a high-frequency electric field having a predetermined frequency for generating the plasma 116 to an inner side of the processing chamber 104. Further, the electric field transmitted inside the waveguide 105 is formed by being oscillated in an electric field generation power supply 106. The frequency of the electric field described above is not particularly limited, but a microwave of 2.45 GHz is used in the present embodiment. Further, a magnetic field generation coil 107 that forms a magnetic field is disposed at a side wall of the vacuum container 101 that constitutes an upper portion of the dielectric window 103 of the processing chamber 104 and a cylindrical portion of the processing chamber 104 and on an outer peripheral side of a lower end of the waveguide 105 in a state of surrounding the side wall of the vacuum container 101 and the outer peripheral side of the lower end portion of the waveguide 105. The electric field of the microwave oscillated by the electric field generation power supply 106 propagates inside the waveguide 105, passes through the dielectric window 103 and the shower plate 102, and is supplied to the processing chamber 104 from above. Further, the electron cyclotron resonance (ECR) is generated by interaction with the magnetic field generated by the magnetic field generation coil 107 and supplied to inside of the processing chamber 104. Atoms or molecules of the processing gas introduced to the inside of the processing chamber 104 via the gas introduction holes 102a of the shower plate 102 are excited and dissociated, so that the high-density plasma 116 is generated in the processing chamber 104.

A wafer placement electrode (first electrode) 120 that constitutes a sample table is provided at a lower portion of the processing chamber 104 and below a space where the plasma 116 is formed. The wafer placement electrode 120 includes a placement surface 120a where a semiconductor wafer (hereinafter, also simply referred to as a wafer) 109 that is a sample (processing target) is placed. The wafer placement electrode 120 is disposed such that the placement surface 120a thereof faces the shower plate 102 or the dielectric window 103. An upper surface 120b of the wafer placement electrode 120 is covered by a dielectric film 140 that constitutes the placement surface 120a. A plurality of conductor films (electrostatic attraction electrodes) 111 for electrostatic attraction connected to a direct-current power supply 126 via a high-frequency filter 125 shown in FIG. 1 are disposed inside the dielectric film 140. Here, the conductor film 111 constitutes the placement surface 120a of the sample table, and is a film electrostatic attraction electrode into which direct-current power for semiconductor wafer attraction by static electricity is supplied. At that time, the conductor film 111 may be bipolar films in which one and the other of a plurality of film electrodes are given different polarities, or a unipolar film given the same polarity, and are shown as the unipolar films in the present embodiment.

A high-frequency power supply (first high-frequency power supply) 124 and a matcher 129 are disposed at places closer to the electrostatic attraction electrodes (conductor films 111) than the high-frequency filter 125. The high-frequency power supply 124 and the matcher 129 are Connected to a circular or cylindrical, conductor electrode base material 108 disposed inside the wafer placement electrode 120. The high-frequency power supply 124 is connected to the ground 112. High-frequency power having a predetermined frequency from the high-frequency power supply 124 (first high-frequency power) is supplied to the electrode base material 108. During processing of the wafer 109, a bias potential is formed above the wafer 109 attracted and held on an upper surface of the wafer placement electrode 120. In other words, the sample table described above includes the wafer placement electrode (first electrode) 120 to which the high-frequency power (first high-frequency power) is supplied from the high-frequency power supply 124 when the plasma 116 is formed.

Inside the electrode base material 108, a refrigerant flow path 152 is disposed in a multiply winding manner to be helical or concentric around a central axis of the electrode base material 108 or the wafer placement electrode 120 in an upper-lower direction in order to cool the wafer placement electrode 120 by removing transmitted heat. The cooling refrigerant for cooling the electrode base material 108 flows through the refrigerant flow path 152.

On an outer peripheral side of an upper portion of the wafer placement electrode 120, a concave portion 120d surrounding the upper portion on an outer peripheral side of the placement surface 120a is disposed. On a ring-shaped upper surface of the concave portion 120d formed lower than the placement surface 120a of the sample table, a susceptor ring 113 that is a ring-shaped member made of a dielectric such as quartz or ceramics such as alumina is placed. In a state where an upper surface of the susceptor ring 113 is placed on the concave portion 120d, the upper surface of the susceptor ring 113 has a dimension higher than the placement surface 120a of the wafer placement electrode 120. The susceptor ring 113 is disposed at an outer peripheral portion of the placement surface 120a of the wafer placement electrode (sample table) 120, and covers a surface of the wafer placement electrode 120. Specifically, the susceptor ring 113 covers the upper surface of the concave portion 120d, a cylindrical side wall surface of the concave portion 120d, and a cylindrical side wall surface of the wafer placement electrode (sample table)) 120 below the concave portion 120d.

In such a plasma etching apparatus 100, in a vacuum transfer chamber depressurized to a pressure the same as that of the processing chamber 104 inside a vacuum transfer container that is another vacuum container coupled to a side wall of the vacuum container 101, the unprocessed wafer 109 is placed on an arm tip end of a wafer transfer robot disposed in the vacuum transfer chamber. A gate that is a passage that communicates the vacuum transfer chamber with the processing chamber 104 is opened by an operation of a valve disposed in the vacuum transfer chamber. The unprocessed wafer 109 described above is transferred into the processing chamber 104 in a state of being placed on the arm tip end of the robot described above. Further, the wafer 109 transferred to above the placement surface 120a of the wafer placement electrode 120 in the processing chamber 104 is transferred onto a lift pin by an upper-lower movement of the lift pin, is placed on the placement surface, and then is attracted and held on the placement surface 120a of the wafer placement electrode 120 by the electrostatic force formed by the direct-current power applied from the direct-current power supply 126.

In this state, a flow rate or a speed of the etching gas is adjusted by a mass flow controller (not shown), and the etching gas is introduced into a space of a gap between the dielectric window 103 and the quartz shower plate 102, is diffused in the space, and then is introduced into the processing chamber 104 through the gas introduction holes 102a of the shower plate 102. Thereafter, by an operation of the vacuum exhaust apparatus, the gas and particles in the processing chamber 104 are exhausted through the vacuum exhaust port 110. According to a balance between an amount of a supply of the gas from the gas introduction holes 102a of the shower plate 102 and an amount of exhaust from the vacuum exhaust port 110, the inside of the processing chamber 104 is adjusted to a predetermined value in a range suitable for processing of the wafer 109.

While the wafer 109 is held by the attraction, a gas having heat transfer properties such as He (helium) is supplied from an opening (not shown) in an upper surface of the dielectric film 140 to a gap between the wafer 109 and the upper surface of the dielectric film 140 that is the placement surface 120a of the wafer placement electrode 120, so that heat transfer between the wafer 109 and the wafer placement electrode 120 is promoted. A refrigerant adjusted to a temperature in a predetermined range flows and circulates in the refrigerant flow path 152 disposed in the electrode base material 108 of the wafer placement electrode 120, so that a temperature of the wafer placement electrode 120 or the electrode base material 108 is adjusted in advance before the wafer 109 is placed. Therefore, the heat transfer is performed between the wafer 109 and the wafer placement electrode 120 or the electrode base material 108 having a large heat capacity, so that the temperature of the wafer 109 is adjusted to be close to a temperature of the wafer placement electrode 120 or the electrode base material 108 before the processing, and heat from the wafer 109 is transferred and the temperature of the wafer 109 is adjusted even after the processing is started.

In the state, the electric field of the microwave and the magnetic field are supplied into the processing chamber 104, and the plasma 116 is generated using the gas. When the plasma 116 is formed, high-frequency (RF: radio frequency) bias power is supplied from the high-frequency power supply 124 to the electrode base material 108, the bias potential is formed above the upper surface of the wafer 109, and charged particles such as ions in the plasma 116 are induced to the upper surface of the wafer 109 according to a potential difference between the bias potential and a potential of the plasma 116. Further, the charged particles described above collide with a surface of a film layer to be processed of a film structure disposed in advance on the upper surface of the wafer 109 and including a mask and the film layer to be processed, thereby performing the etching. During the etching, the processing gas introduced into the processing chamber 104 and particles of a reaction product generated during the processing are exhausted from the vacuum exhaust port 110. In the plasma etching apparatus 100 according to the present embodiment, during the plasma processing, second high-frequency power is supplied from a high-frequency power supply (second high-frequency power supply) 127 to a conductor ring (second electrode) 131 disposed on an upper portion of the outer peripheral portion of the sample table described above via a power supply connector 161 (described later) provided on the sample table described above and including a conductive member having elasticity.

In the wafer placement electrode 120 according to the present embodiment, an alternating-current high voltage generated from the high-frequency power supply (second high-frequency power supply) 127 is introduced into the conductor-made conductor ring (second electrode) 131 disposed in the susceptor ring 113 via a matcher 128 of a load and a load impedance variable box 130. With this configuration, by combination of the load impedance variable box 130 adjusted to a suitable impedance value and a portion having a relatively high impedance and disposed on an upper portion of the susceptor ring 113, an impedance value for high-frequency power from the high-frequency power supply 127 through the electrode base material 108 to an outer peripheral edge of the wafer 109 is relatively reduced. Accordingly, it is possible to effectively supply the high-frequency power to the outer peripheral side portion and the outer peripheral edge of the wafer 109, and to relieve concentration of the electric field at the outer peripheral side portion or the outer peripheral edge, thereby inducing the charged particles such as the ions in the plasma to the upper surface of the wafer 109 in a desired direction. The high-frequency power supply 127 is connected to the ground 112. A frequency of the high-frequency power supply 127 in the present embodiment is preferably set to a value the same as or a constant multiple of that of the high-frequency power supply 124.

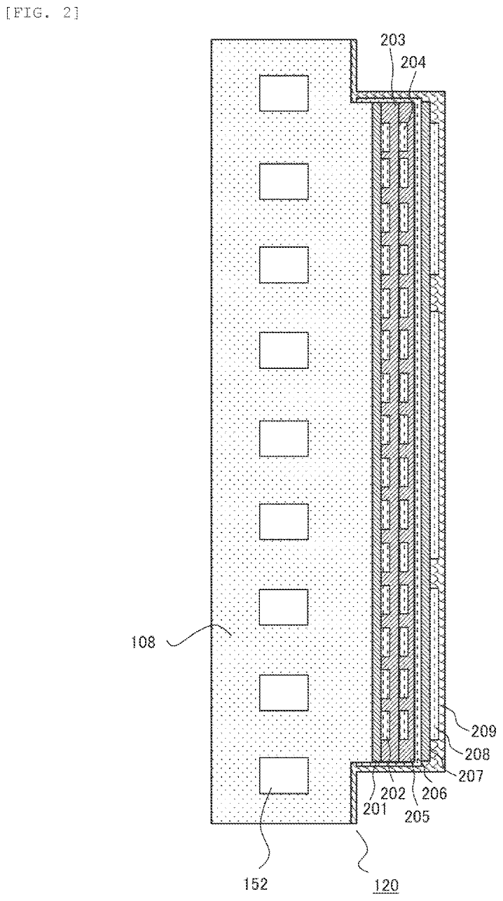

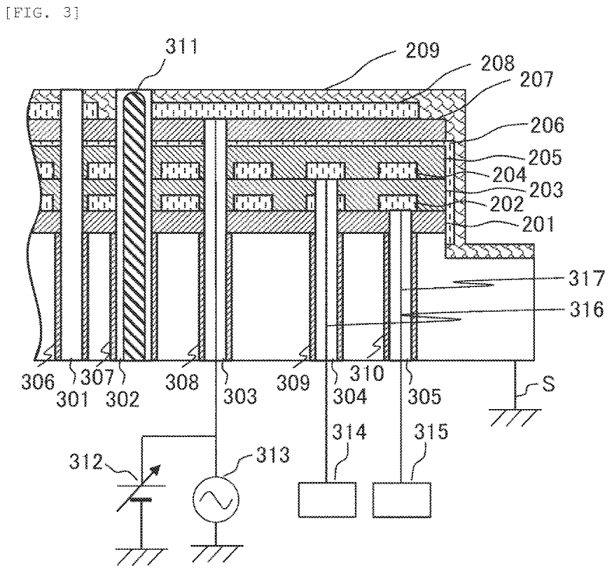

Next, a configuration of the sample table 120 according to the present embodiment will be described in detail with reference to FIGS. 1, 2, and 3. FIG. 2 is a cross-sectional view schematically showing a part of the configuration of the sample table of the plasma processing apparatus shown in FIG. 1. FIG. 3 is a partially enlarged cross-sectional view schematically showing a part of the configuration of the sample table of the plasma processing apparatus shown in FIG. 2.

In the present embodiment, the base material 108 disposed in the sample table 120 shown in FIG. 2 and having a disk shape or a cylindrical shape is made of a metal material such as titanium, aluminum, or a compound thereof, is electrically connected to a ground electrode S, is coupled to a wall surface of the vacuum container 101 shown in FIG. 1 so as to be conductive, and is fixed to a ground potential. The base material 108 includes a convex portion in a central portion, and a concave portion that is disposed in a ring shape on an outer peripheral side of the convex portion so as to surround the convex portion. The convex portion allows the wafer 109 to be placed thereon. The concave portion has an upper surface formed with a low height. Between the convex portion and the concave portion, a step portion that constitutes a side wall of an outer periphery of the convex portion is provided. As described above, the susceptor ring 113 made of the ceramic material is placed on the ring-shaped concave portion.

A dielectric film 201 that is a film made of a dielectric material such as ceramics is disposed on a flat upper surface of the convex portion of the base material 108. Further, a plurality of first heater films (also referred to as first heater layer) 202 that are film electrodes made of a conductive material and that generate heat due to the direct-current power being supplied are disposed above a film layer of the dielectric film 201 to cover a plurality of regions on the upper surface of the base material 108. That is, the dielectric film 201 is disposed on the upper surface of the base material 108, and the heater films 202 that are film-shaped heaters are formed on the dielectric film 201.

The heater films 202 are further covered by an upper dielectric film 203, and surroundings of the heater films 202 are surrounded by a dielectric member (dielectric film 203). In the sample table 120 according to the present embodiment, a plurality of second heater films (also referred to as second heater layer) 204 that are film electrodes made of the conductive material having the same structure as that described above and that generate heat due to the direct-current power being supplied are disposed above the dielectric film 203 that covers the heater films 202 disposed on an upper portion of the dielectric film 201 to cover the plurality of regions on the upper surface of the base material 108. Further, a dielectric film 205 is disposed to cover the heater films. That is, the first heater films 202 surrounded by the dielectric films 201 and 203 are disposed on the upper surface of the base material 108, and the second heater films 204 surrounded by the dielectric films 203 and 205 are disposed on the upper surface in a similar manner as described above.

The plurality of heater films 202 and 204 are connected to direct-current power supplies 314 and 315 whose operation is adjusted according to a command signal from a controller via power supply cables (power supply wires, power supply paths) 316 and 317, and are configured such that the direct-current power can be supplied by the direct-current power supplies 314 and 315. That is, the power supply cables 316 and 317 are cables that electrically connect the heater films 202 and 204 to the direct-current power supplies 314 and 315 that supply the direct-current power to the heater films 202 and 204. However, the power supply cables 316 and 317 do not include high-frequency power filters. As described above, the inside of the dielectric film 201 disposed on the upper surface of the sample table 120 according to the present embodiment includes a configuration including the plurality of first heater films 202 (referred to as multi-zone heaters) and the plurality of second heater films 204. The first heater films 202 can adjust a heat generation amount for each region (zone), thereby adjusting a temperature of an upper surface of the dielectric film 201. The second heater films 204 are above the plurality of first heater films 202 and can adjust a temperature of an upper surface.

In the sample table 120 according to the present embodiment, the first heater films 202 surrounded by the dielectric films 201 and 203 are disposed on the upper surface of the base material 108, and the second heater films 204 surrounded by the dielectric films 203 and 205 are disposed on the upper surface in a similar manner as described above. Further, an upper surface of the dielectric film 205 is provided with a shield film 206 that is a film member that surrounds an upper portion and an outer periphery of a peripheral edge and that has conductivity. The heater films 202 and 204 are surrounded (covered) by the shield film 206. In other words, the structure in which the heater films 202 and 204 are surrounded by the shield film (conductor film) 206 is enclosed within the dielectric material that constitutes a part of the dielectric films 201, 203, and 205. The shield film 206 is electrically connected to the base material 108. Accordingly, the shield film 206 is fixed to a ground potential like the base material 108. As a result, it is possible to prevent inflow of a high frequency into the heater films 202 and 205.

A dielectric film 207 is disposed on an upper surface of the shield film 206. An electrode film 208 is disposed on an upper portion of the member of a dielectric material. The electrode film 208 is an electrostatic attraction electrode and an electrode to which high-frequency power is supplied for high-frequency bias formation. That is, the electrode film 208 is a film made of a conductor material, and is electrically connected to a high-frequency bias power supply 313 that supplies high-frequency power having a predetermined frequency. A direct-current power supply 312 is also electrically connected to the electrode film 204, and is applied with a direct-current voltage, whereby the wafer 109 placed on the placement surface of the sample table 120 can be attracted by the static electricity.

Above an upper surface of the electrode film 208, a dielectric film (electrostatic attraction member) 209 covers the upper surface of the convex portion, the concave portion surrounding the upper surface of the convex portion, and the step portion that is the side wall of the convex portion. The dielectric film (electrostatic attraction member) 209 is an uppermost surface of the sample table 120, and is made of a ceramic material that constitutes the placement surface on which the wafer 109 is placed. That is, the dielectric film 209 including the electrode film (electrode) 208 that attracts the wafer 109 by the electrostatic force disposed on an upper portion of the shield film 206 on the shield film 206 is disposed on the uppermost surface of the sample table 120.

The sample table 120 has a plurality of through holes that penetrate through a space between an upper surface of the dielectric film 209 on the convex portion and a bottom surface of the base material 108. The through holes include a plurality of lift pin through holes 302 that house lift pins (pins) 311 and a heat transfer gas supply hole 301. The lift pin through holes 302 house lift pins (pins) 311 each of which moves up and down inside the through hole to support the wafer 109 from below and move the wafer 109 above the upper surface of the sample table 120. The heat transfer gas supply hole 301 allows a heat transfer gas such as He supplied to a gap between the upper surface of the dielectric film 209 and a back surface of the wafer 109 placed on the upper surface of the dielectric film 209 to flow through. The lift pin 311 disposed in the lift pin through hole 302 raises or lowers the wafer 109 above the upper surface of the dielectric film 209. Here, the plurality of lift pin through holes 302 are opened in the upper surface of the dielectric film 209, and penetrate through the dielectric films 201, 203, 205, and 206. An electrostatic attraction power supply hole 303, a heater power supply hole 305, and a heater power supply hole 304 are disposed in the sample table 120. The electrostatic attraction power supply hole 303 has therein a connector and a power supply cable for applying the power to the electrode film 208. The heater power supply hole 305 has therein a connector and a power supply cable that supplies the power to the first grit-shaped heater films 202. The heater power supply hole 304 has therein a connector and a power supply cable that supplies the power to the second ring-shaped heater films 204.

In these holes, wall surfaces of inner peripheries of portions that penetrate through the inside of the base material 108 are provided with insulation bosses 306, 307, 308, 309, and 310 that are cylindrical members made of a dielectric material or an insulation material. That is, the base material 108 of the sample table 120 is formed with the insulation bosses 306, 307, 308, 309, and 310 that constitute the inner peripheral wall surfaces of the base material 108 in the base material 108 and that are cylindrical members made of an insulation material disposed in the plurality of through holes. The insulation bosses 306, 307, 308, 309, and 310 can prevent occurrence of discharge in a space in a hole exposed to an electric field of the high-frequency power during processing of the wafer 109. Ceramic materials such as alumina and yttria, or resin materials can be used as a material that forms the insulation bosses 306, 307, 308, 309, and 310.

In the present embodiment, devices that adjust an operation of the plasma etching apparatus 100 each include a detector that detects a state of an operation such as an output, a flow rate, and a pressure, or a plurality of temperature sensors disposed in the base material 108 of the wafer placement electrode 120, and are communicably connected to a control unit 170 via wired or wireless communication. The devices that adjust an operation of the plasma etching apparatus 100 include devices that constitute an electric field and magnetic field adjustment system such as the electric field generation power supply 106, the magnetic field generation coil 117, the high-frequency power supply 124, the high-frequency filter 125, the direct-current power supply 126, the high-frequency power supply 127, the matchers 128 and 129, and the load impedance variable box 130, and the direct-current power supplies 314 and 315 that supply the power to the first heater films 202 and the second heater films 204 in the dielectric film 201, or a pressure adjustment system such as the vacuum exhaust apparatus described later or the mass flow controller that adjusts a gas supply amount.

When a signal indicating a state of the operation output from the detector provided in each of the devices is transmitted to the control unit 170, an arithmetic unit of the control unit 170 reads software stored in a storage device in the control unit 170, detects an amount of the state from the signal from the detector received based on an algorithm thereof, and calculates and transmits a command signal for adjusting the amount of the state to an appropriate value. A device provided in the electric field and magnetic field adjustment system or the pressure adjustment system that receives the command signal adjusts an operation according to the command signal.

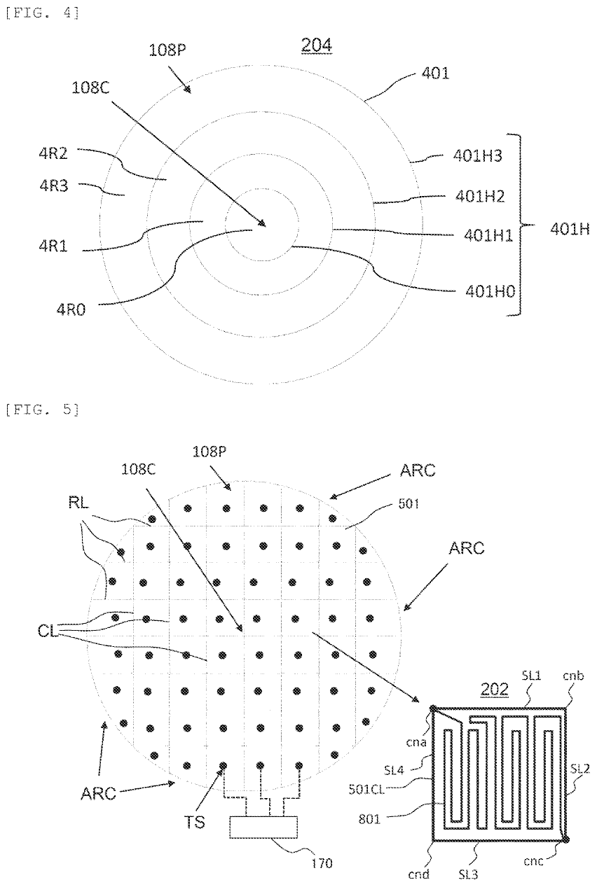

FIG. 4 is a diagram showing an example of the second heater film in the sample table. A heater disposition 401 is an example of a configuration of the plurality of ring-shaped second heater films 204 in the sample table 120. A heater wire is provided in each heater film 204, and an object thereof is to perform temperature control according to a reaction product distribution and a plasma density distribution during the plasma processing on the wafer 109.

The second heater layer 204 includes a plurality of film-shaped heater portions 401H (401H0, 401H1, 401H2, and 401H3). The plurality of film-shaped heater portions 401H (401H0, 401H1, 401H2, and 401H3) are disposed in three or more regions in a radial direction (4R0, 4R1, 4R2, and 4R3) on a plurality of radii in a radial direction from a center (108C) toward an outer periphery (108P) of the upper surface of the base material 108 of the sample table 120 above the first heater layer 202 in the dielectric films (dielectric films 203 and 205). The three or more regions include a circular region concentrically disposed around a center and ring-shaped regions that surround an outer periphery of the circular region.

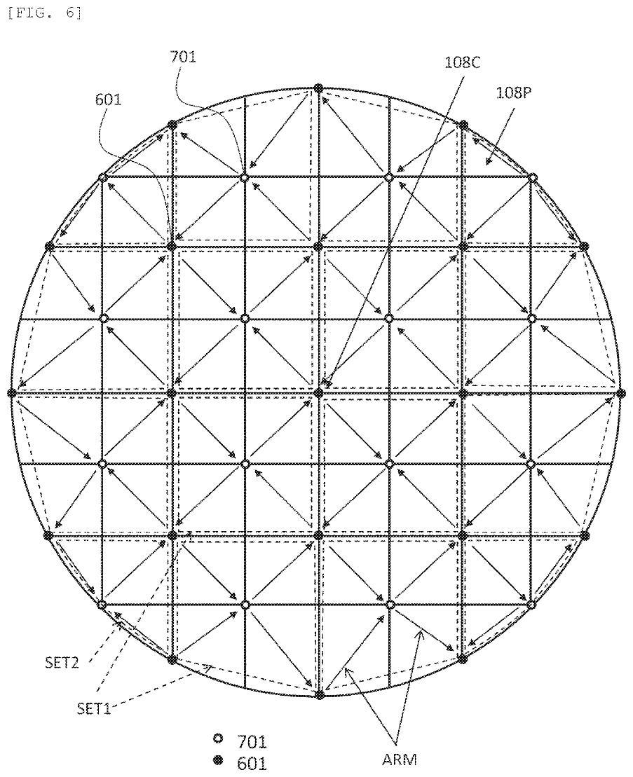

FIG. 5 is a diagram showing an example of disposition of the first heater films provided in the sample table of the plasma processing apparatus according to the present embodiment. The film-shaped heater first films 202 according to the present embodiment are metal film-shaped heaters disposed in the dielectric film 140 that covers the circular upper surface of the base material 108 by forming a plurality of layers, and are disposed in a plurality of regions 501 corresponding to circuit patterns of a plurality of semiconductor devices formed in advance on the upper surface of the wafer 109 placed on the upper surface of the dielectric film 209 when viewed from above. In the circular base material 108 of the sample table 120, at an outer peripheral edge of the upper surface of the dielectric film 201, the regions 501 do not have a completely rectangular shape, and some of the region 501 have an arc-shaped shape ARC.

During the plasma processing, the first heater film 202 is provided to perform the temperature adjustment for each circuit pattern (also referred to as a die or a chip region) of the semiconductor device formed on the wafer 109.

For example, as shown in an enlarged manner in FIG. 5, the first heater film 202 includes a rectangular outer frame wiring portion 501CL and an inner wiring portion 801 formed inside the outer frame wiring portion 501CL in a rectangular region 501. For example, among four corners of the outer frame wiring portion 501CL (the first corner cha, the second corner cnb, the third corner cnc, and the fourth corner cnd), the inner wiring portion 801 is connected between a pair of diagonal corners (cna and cnc). The pair of corners (cna and cnc) are diagonal corners. The inner wiring portion 801 is a film-shaped heater wire, and is implemented by, for example, zigzag heater wiring (also referred to as meandering wiring) between a pair of diagonal corners (RLC1 and RLC2) of the outer frame wiring portion 501CL so as to be able to heat an entire region in the outer frame wiring portion 501CL. The outer frame wiring portion 501CL has a first side SL1 provided between the first corner cna and the second corner cnb, a second side SL2 provided between the second corner cnb and the third corner cnc, a third side SL3 provided between the third corner cnc and the fourth corner cnd, and a fourth side SL4 provided between the fourth corner cnd and the first corner cna. The first side SL1 and the third side SL3 are provided facing each other, the second side SL2 is provided between the first side SL1 and the third side SL3, and the fourth side SL4 is provided facing the second side SL2.

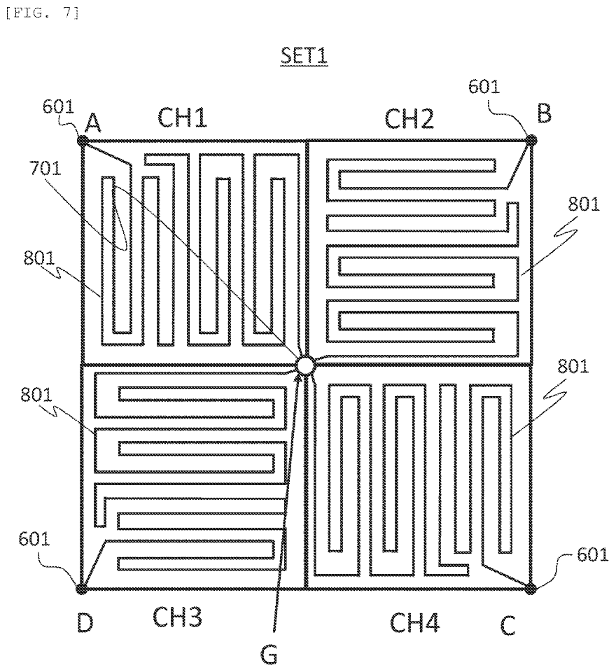

The outer frame wiring portion 501CL of the first heater film 202 is formed in a rectangular shape conforming to an outer shape of each of the plurality of regions 501 partitioned in a grid shape by a plurality of first line segments (RL) and a plurality of second line segments (CL) when viewed from above inside each rectangular region 501, so that the upper surface of the dielectric film 201 Corresponds to a shape of the die of the semiconductor device. The first line segments (RL) extend in a front-rear direction and are parallel to one another at equal intervals. The second line segments (CL) extend in the front-rear direction at equal intervals and are perpendicular to the plurality of first line segments (RL). Since the regions 501 do not completely have a rectangular shape, and some of the regions 501 have the arc-shaped shape ARC at the outer peripheral edge portion of the upper surface of the dielectric film 201, the outer frame wiring portion 501CL is formed in a shape conforming to an outer shape of the regions 501 having the arc-shaped shape ARC correspondingly (for this, FIG. 6 can be referred to).

The number of regions 501 of the first heater film 202 according to the present embodiment is larger than the number of regions 401 of the plurality of ring-shaped second heater films 204 shown in FIG. 4. While the number of regions 401 is 3 to 40, the number of regions 501 can be 10 to 200. In each region 501, a thin metal film with a small width that constitutes the first heater layer 202 is folded in a horizontal direction a plurality of times along a side of a rectangular outer shape, and is provided with a rectangular film-shaped heater wire (801).

In the present embodiment, by adjusting the power supplied to a plurality of film-shaped heaters (801) formed along shapes of the regions 501 corresponding to the die of the semiconductor device during the plasma processing, a temperature of the wafer 109 can be accurately adjusted for each place corresponding to the die of the semiconductor device of the wafer 109 on the upper surface of the wafer 109. Particularly, a variation in a result of the etching on the wafer 109 can be reduced by performing adjustment according to the dies of the manufactured semiconductor device. Here, a film thickness of the plurality of film-shaped heaters implemented by the second heater layer 204 is larger than a film thickness of the plurality of film-shaped heaters 801 implemented by the first heater layer 202.

For each heater zone (501) of the first heater film 202 corresponding to the die of the semiconductor device of the wafer 109 shown in FIG. 5, a plurality of temperature sensors TS are disposed in the base material 108 below the heater zones (501). The plurality of temperature sensors TS and the control unit 170 are electrically connected to each other by, for example, metal wiring. Values of temperatures measured and detected by the plurality of temperature sensors TS are transmitted to the control unit 170 via the metal wiring.

Upon receiving outputs from the temperature sensors TS, the control unit 170 detects a temperature of the upper surface of the base material 108 or the surface of the dielectric film 201 corresponding to the zones (501) by following an algorithm of software stored in an internal storage device. Further, based on the detected temperature, by following the similarly read algorithm of the software, the control unit 170 adjusts an amount of the direct-current power supplied to the heater wires (801) of the zones (501) to adjust a heat generation amount of the heater wires (801) of the zones (501) or a heating amount of the base material 108. That is, the control unit 170 performs feedback control based on the detected temperature corresponding to the outputs from the plurality of temperature sensors TS such that the heat generation amount of the film-shaped heater wires (801) that constitute the first heater layer (202) of the zones (regions 501) or the heating amount of the base material 108 become a desired target heat generation amount or a desired target heating amount.

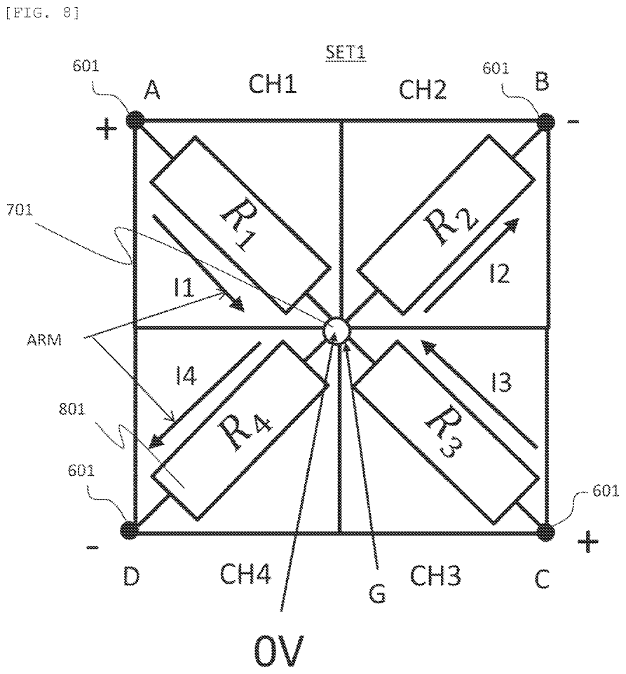

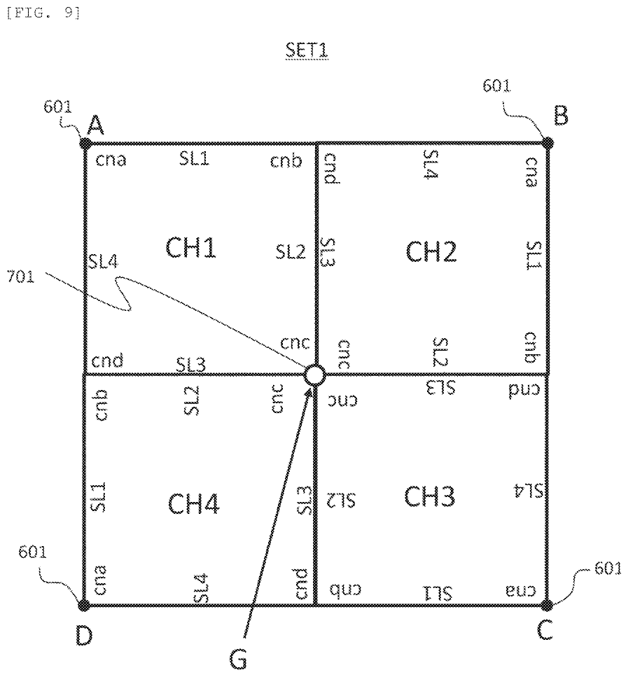

In the present embodiment, the heater wires (801) under the feedback control are the first heater film 202. The second heater film 204 maintains a predetermined power supply amount to the heaters in the ring-shaped zones (4R0, 4R1, 4R2, and 4R3) in which the circular or arc-shaped regions shown in FIG. 4 are connected for each type of film structure of each wafer 109 or the upper surface of the wafer 109, or for each group (lot) of a predetermined number of wafers 109. That is, in the plasma processing of any wafer 109, a heat generation amount of the second heater films 204 is fixed, and temperatures of the first heater films 202 (heater wires 801) are adjusted according to temperatures obtained by the outputs from the temperature sensors TS. In other words, the control unit 170 adjusts an output of the film-shaped heater 801 disposed in one of rectangular regions of the first heater layer 202 (regions 501, CH1 to CH4 in FIGS. 7 and 8) while maintaining outputs of the heaters of the second heater layer 204 located above one of rectangular regions corresponding to the dies of the semiconductor device (regions 501, CH1 to CH4 in FIGS. 7 and 8) according to the outputs from the plurality of temperature sensors TS.

Next, a method for arranging current supply portions (601, hereinafter, also referred to as a power supply portion) and return places (701, hereinafter, also referred to as a current return portion) of the first grid-shaped heater (first heater film 202) according to the present embodiment will be described with reference to FIG. 6. FIG. 6 is a top view schematically showing disposition of the second heaters and the power supply portions (601) and the current return portions (701) for the heaters disposed in the region on a plurality of grids on the sample table according to the present embodiment shown in FIG. 5. FIG. 6 shows a disposition example of the power supply portions (601) and the current return portions (701) together with the disposition of the grid heaters (first heater films 202).

Features of the disposition method are as follows.

1) Connector portions of either the supply portion (601) or the return place (701) (white circle ∘: a connection region of the return place (701), black circle ●: a connection region of the supply portion (601)) are disposed at two diagonal corners of each rectangular grid.

2) With a set of four regions 501 being as one set (SET1), each set (SET1) includes one current return portion 701 and four power supply portions (also referred to as power supply paths) 601. SET1 is a set of four grid-shaped regions 501 in which each region 501 is adjacent to two regions belonging to the set in a manner that sides of rectangles face each other in a front-rear direction (upper-lower direction in the drawing) and a left-right direction (left-right direction in the same). That is, the four grid-shaped regions 501 constitute a region having a rectangular shape as a whole with the two regions 501 each connected in the front-rear and left-right directions. The current return portion (also referred to as a return path) 701 is disposed at a central portion of an entire region that is a corner of the four grid-shaped regions 501. The power supply portion 601 of each region 501 is disposed at a corner in a diagonal place of a corner where the current return portion 701 is disposed. That is, in one set (SET1) including the four grids (each grid corresponds to one region 501), the current return portion (701) is disposed at the central portion, and the power supply portions (601) are disposed at the four corners. In other words, with the four film-shaped heaters 801 disposed in the four regions (CH1 to CH4) being one set, each set includes four power supply paths (power supply portions 601) and one return path (701). The four power supply paths are electrically connected to one place (A, B, C, D) of each of the set of film-shaped heaters 801 and supply the power from the direct-current power supply. The one return path is electrically connected to another place (G) of each film-shaped heater and allows the power to return to the direct-current power supply.

3) Therefore, in the first heater 202 in each region 501 according to the present embodiment, a current flows from places connected to connectors of the power supply portions 601 disposed at corners of the four regions 501 toward a central portion or a center of the entire region (SET1) of the set of four regions 501. That is, as indicated by arrows in FIG. 6, the current flows from the four corners (corners where the power supply portions 601 are disposed) toward the central portion (a portion where the current return portion 701 is disposed), or the current flows from the corners (power supply portions 601) toward the center (current return portion 701), or the current flows from the central portion (current return portion 701) toward the corners (power supply portions 601).

4) On boundaries of the grids in the front-rear and left-right directions that partition the regions 501 disposed in a lattice shape, the connector portion of the power supply portion 601 and the connector portion of the current return portion 701 are alternately disposed at each boundary (corner) of the two regions 501.

5) In the present embodiment, one boundary among a plurality of boundaries that partition the plurality of regions 501 partitioned in the grid shape in the front-rear and left-right directions is disposed through the center of the upper surface of the base material 108 or the dielectric film 203 having the circular shape. However, since four rectangular regions 501 in which any two regions 501 are adjacent to each other cannot be formed as one set at the outer peripheral edge of the dielectric film 203 having the circular shape, three grid-shaped regions 501 are disposed as one set. Such a set of regions 501 or second heater films 202 at the outer peripheral edge may include two or three regions 501 or second heater films 202. That is, at the outer peripheral edge of the heater where the set (SET1) cannot be formed by four grids, the connector portion of the supply portion 601 and the connector portion of the current return portion 701 are disposed in a set (SET2) including three grids.

6) The connector portion of the current return portion (701) is made of a conductive material, and is connected to the base material 108 grounded and electrically set to be a ground potential by Tungsten via wiring. With this configuration, a current supplied to the first heater film 202 flows through the current return portion 701 to the base material 108 set to be at a constant voltage (ground potential). This can reduce the number of through holes (holes) that house cables that constitute a return path for returning a current supplied to the first heater films 202 to the power supply, and can reduce manufacturing man-hours and a cost of the sample table 120 or the plasma processing apparatus. That is, since the return current flows to the base material 108, a processing number of return current holes required for the base material 108 can be reduced. Via processing is performed on the base material 108, and the Tungsten via wiring is performed on the first heater layers 202 and the base material 108, so that a return current of the heater wires 801 can be collected in the base material 108.

Next, with reference to FIGS. 7 and 8, a configuration will be described in which a polarity of the power supply portion 601 of the film-shaped heater wire 801 that constitutes the first heater film 202 in the set (SET1) of the four regions 501 is reversed. FIG. 7 is a top view schematically showing an outline of the configuration of the first heater film 202 of the set (SET1) of the four regions in the sample table 120 shown in FIG. 6. The heater wire (801) of the first heater 202 in each region 501 is shown in an enlarged manner. FIG. 8 is a diagram schematically showing a current that flows through the first heater films 202 between the power supply portions 601 and the current return portion 701 in the set (SET1) of the four regions shown in FIG. 7. FIG. 8 is an equivalent circuit diagram in which the four heater wires 801 shown in FIG. 7 are rewritten as four resistance elements (R1, R2, R3, and R4). Further, in FIG. 8, a relative magnitude of a potential of the power supply portion 601 with respect to a potential of the current return portion 701 (a ground potential in the present embodiment) is shown as positive and negative polarities. Positive and negative signs (+, −) and disposition in FIG. 8 represent the potential of the power supply portion (601) with “+” when the potential is higher and “−” when lower than the potential of the return portion 701.

As shown in FIGS. 7 and 8, each set (SET1) includes four grids, and the four grids include four regions (CH1, CH2, CH3, and CH4) corresponding to a quadratic die of the semiconductor device. The set (SET1) has a rectangular shape in a plan view and includes four corners (A, B, C, and D) and a center point (G). The four corners (A, B, C, and D) are disposed in an order of the first corner A, the second corner B, the third corner C, and the fourth corner D clockwise in the plan view. Here, the first corner A and the third corner C correspond to a pair of diagonal corners. Further, the second corner B and the fourth corner D Correspond to another pair of diagonal corners.

The first region CH1 is disposed at a rectangular portion between the first corner A and the center point (G), The power supply portion 601 is disposed at the first corner A, and the current return portion 701 is disposed at the center point (G). The heater wire (801) is connected between the power supply portion 601 of the first corner A and the current return portion 701 of the center point (G).

The second region CH2 is disposed at a rectangular portion between the second corner B and the center point (G). The power supply portion 601 is disposed at the second corner B. The heater wire (801) is connected between the power supply portion 601 of the second corner B and the current return portion 701 of the center point (G).

The third region CH3 is disposed at a rectangular portion between the third corner C and the center point (G). The power supply portion 601 is disposed at the third corner C. The heater wire (801) is connected between the power supply portion 601 of the third corner C and the current return portion 701 of the center point (G).

The fourth region CH4 is disposed at a rectangular portion between the fourth corner D and the center point (G). The power supply portion 601 is disposed at the fourth corner D. The heater wire (801) is connected between the power supply portion 601 of the fourth corner D and the current return portion 701 of the center point (G).

The first region CH1 and the second region CH2 are rotationally symmetric about the center point (G). Similarly, the first region CH1 and the third region CH3 as well as the first region CH1 and the fourth region CH4 are also rotationally symmetric about the center point (G). Further, it can also be said that the four regions including the first region to the fourth region (CH1 to CH4) each have one side of the rectangle facing an adjacent region.

In other words, the current return portion 701 that is the return path is disposed at the place (G) where the four corners of the four rectangular regions (CH1 to CH4) adjacent to one another when viewed from above are adjacent to one another. In the four rectangular regions (CH1 to CH4), the power supply portions (601) that are the power supply paths are connected to the corners (A, B, C, and D) at diagonal positions of the corner to which the return path (701) is connected.

FIG. 9 is a schematic diagram showing a relationship between the four corners (the first corner cna, the second corner cnb, the third corner cnc, and the fourth corner cnd) as well as the four sides (the first side SL1, the second side SL2, the third side SL3, and the fourth side SL4) of the rectangular region 501 described in FIG. 5 and the four regions in FIG. 7 (the first region CH1, the second region CH2, the third region CH3, and the fourth region CH4).

Since the second region CH2 is disposed by rotating the first region CH1 by 90 degrees to the right with respect to the center point (G) or the third corner cnc, the second side SL2 of the first region CH1 and the third side SL3 of the second region CH2 overlap with each other. Similarly, since the third region CH3 is disposed by rotating the second region CH2 by 90 degrees to the right with respect to the center point (G), the second side SL2 of the second region CH2 and the third side SL3 of the third region CH3 overlap with each other. Since the fourth region CH4 is disposed by rotating the third region CH3 by 90 degrees to the right with respect to the center point (G), the second side SL2 of the third region CH3 and the third side SL3 of the fourth region CH4 overlap with each other. The second side SL2 of the fourth region CH4 and the third side SL3 of the first region CH1 overlap with each other.

That is, the four regions including the first region to the fourth region (CH1 to CH4) each have one side of the rectangle (the second side SL2 and the third side SL3) facing an adjacent region adjacent (the first region CH1 and the second region CH2, the second region CH2 and the third region CH3, the third region CH3 and the fourth region CH4, and the fourth region CH4 and the first region CH1). The center point (G) is adjacent to the third corners cnc of the four regions (the first region CH1, the second region CH2, the third region CH3, and the fourth region CH4).

As shown in FIG. 8, as compared with the connector portion of the current return portion 701 set to a ground potential (0V), for at least one of the connector portions of the power supply portions 601 located at the diagonal corners (B and D) among the corners (A, B, C, and D) of the four regions 501 where the current return portion 701 is disposed, a potential thereof is set to a negative potential (−). In the present embodiment, polarities of potentials of the connector portions set to values of positive potentials (+) in the two power supply portions 601 are reversed to values of the negative potentials (−) in the other two power supply portions 601. In other words, potential of at least one place (A, B, C, or D) where the film-shaped heaters (801) are connected to the power supply portions (601) that are the four power supply paths is lower than a potential (0V: ground potential) of the place (G) where the film-shaped heaters (801) are connected to one return path (701) (negative potential (−)).

Accordingly, in the set of four grids (SET1), currents (I1 and I3) that flow from the power supply portions 601 set to the values of the positive potentials (+) through the first heater films 202 (the heater wires 801: the resistance elements R1 and R3) to the current return portion 701, and currents (I2 and I4) that flow from the current return portion 701 through the first heater films 202 (the heater wires 801: the resistance elements R2 and R4) to the power supply portions 601 set to the values of the negative potentials (−) are at least partially canceled. Accordingly, it is possible to reduce a current that flows through the return path from the current return portion 701 toward the power supply. Accordingly, it is possible to reduce a size of the return path, and to prevent an increase in a volume of the sample table 120.

Next, with reference to FIGS. 6 and 8, a case will be described where in the set of regions 501 including the four grids (SET1), the number of power supply portions (601) whose polarities are reversed (the number of negative potentials (−) in which a potential is lower than that of the current return portion 701), and the number of power supply portions (601) whose polarities are not reversed (the number of positive potentials (+) in which a potential is higher than that of the current return portion 701) are equal to each other. In FIGS. 6 and 8, directions of arrows ARM in the drawings indicate directions in which the current flows. Symbols of electrical resistance will be omitted as appropriate in FIG. 6. In the examples in FIGS. 7 and 8, in the set of four regions 501 (SET1), the number of power supply portions 601 having potentials (+) higher than that of the current return portion 701 (two) is set to two, which is the same as the number of power supply portions 601 having potentials (0−) lower than that of the current return portion 701 (two).

In such a configuration, it is possible to reduce the return current of the current return portion (701) under processing conditions in which a distribution of temperature values during processing of the region of the dies of the semiconductor devices on the wafers 109 corresponding to the grid-shaped regions 501 shown in FIGS. 5 and 6 has rotational symmetry with respect to the center point 108C of the base material 108.

This is because it can be said that when the temperature conditions during the processing of the wafer 109 have the rotational symmetry, in order to implement the distribution of the temperatures by heating the wafer 109, a heat generation amount of the first heater film 202 adjusted for each region 501 also needs to have the rotational symmetry in the same manner. When a thermal resistivity of the heater wire 801 of the first heater film 202 is equal between the regions 501, or approximate to the extent that can be regarded as equal, it can be said that the same rotational symmetry is also necessary for the current that flows to the first heaters 202 of the regions 501.

That is, the set of four grid-shaped regions 501 (SET1) has rotational symmetry with respect to the center (G). In the configuration, when the number of power supply portions 601 (the number of positive potentials (+)) and the number of power supply portions 601 whose polarities are not reversed (the number of negative potentials (−)) are equal to each other, magnitudes of the currents (I1, I2, I3, and I4) that flow to the heater wires 801 located at line-symmetric or point-symmetric positions with respect to the center point G (current return portion 701) are equal, and the apparent current that flows to the electrode base material 108 is guaranteed to be half as compared with a case where the polarities are not reversed.

Under conditions in which surface temperatures of an electrode base material 108 are equal over the entire surface (hereinafter, referred to as flat temperature conditions), the currents that flow in the set of four grids (SET1) are equal, and no current flows to the current return portion 701.

At the outer peripheral edge 108P, even at the heater wires 801 at ends of three electrodes to which the current return portion 701 is common, the temperatures of the heater wires 801 are substantially equal under the flat temperature conditions or temperature conditions in which a temperature near a center of an electrode is high. At this time, it is expected that the return current of the current return portion 701 can be controlled to about one-third of that in the case where the polarities are not reversed.

When no polarity is reversed, the current that flows to the electrode base material 108 increases as the number of heater wires 801 is increased. Joule heat is generated in the base material 108 in proportion to a square of the magnitude of the current that flows to the base material 108, which influences the temperature control of the wafer 109. Alternatively, it is also expected that a large amount of current that flows to the base material 108 is a risk during an electric shock.

### REFERENCE SIGNS LIST

101: vacuum container
104: processing chamber
108: base material
109: wafer (sample)
120: sample table
140: dielectric film
202: first heater layer 202
501, CH1, CH2, CH3, CH4: region
601: power supply portion (power supply path)
701: current return portion (return path)
801: film-shaped heater
TS: temperature sensor
SET1: set of regions
A, B, C, D: corner
G: center point

1. A plasma processing apparatus comprising:
a processing chamber disposed in a vacuum container and configured to allow a wafer to be processed to be disposed and allow plasma to be formed in the processing chamber;
a cylindrical sample table disposed in the processing chamber, the sample table having an upper surface configured to allow the wafer to be placed;
a first heater layer disposed in a dielectric film covering an upper surface of a disk-shaped base material of the sample table, the first heater layer including a plurality of film-shaped heaters respectively disposed in a plurality of regions having a rectangular shape; and
a plurality of temperature sensors disposed in the base material below the rectangular regions of the first heater layer, wherein
the plurality of regions are disposed corresponding to circuit patterns of a plurality of semiconductor devices formed on an upper surface of the wafer, and include four regions in which each of the plurality of regions has one side of the rectangle facing an adjacent region, and
with the film-shaped heaters disposed in the four regions being one set, each set includes four power supply paths and one return path, the four power supply paths being electrically each connected to one place of each of the film-shaped heaters of the set and being configured to supply power from a direct-current power supply, the one return path being electrically connected to another place of each of the film-shaped heaters and being configured to allow the power to return to the direct-current power supply.

2. The plasma processing apparatus according to claim 1, further comprising:
a second heater layer, wherein
the second heater layer is disposed above the first heater layer in the dielectric film, and includes a plurality of film-shaped heaters respectively disposed in three or more regions in a radial direction, the regions being concentrically disposed around a center of an upper surface of the base material of the sample table on a plurality of radii in a radial direction from the center toward an outer periphery, and including a circular region and ring-shaped regions that surround an outer periphery of the circular region.

3. The plasma processing apparatus according to claim 1, wherein
the return path is made of a conductive material and is connected to the base material set to ground potential.

4. The plasma processing apparatus according to claim 3, wherein
the return path is disposed at a place where four corners of the four regions adjacent to one another when viewed from above are adjacent to one another, and
in the four regions, the power supply path is connected to a corner at a diagonal position of a corner where the return path is connected.

5. The plasma processing apparatus according to claim 1, further comprising:
a control unit configured to adjust an output of the film-shaped heaters that constitute the first heater layer according to outputs from the plurality of temperature sensors.

6. The plasma processing apparatus according to claim 1, further comprising:
a control unit configured to adjust outputs of the plurality of film-shaped heaters that constitute the first heater layer according to outputs from the plurality of temperature sensors, wherein
a potential of at least one place where each of the film-shaped heaters is connected to four power supply paths is lower than a potential of a place where each of the film-shaped heaters is connected to one return path.

7. The plasma processing apparatus according to claim 2, further comprising:
a control unit configured to adjust an output of the film-shaped heater disposed in one of the rectangular regions of the first heater layer while maintaining an output of a heater of the second heater layer located above one of the rectangular regions according to outputs from the plurality of temperature sensors.

8. The plasma processing apparatus according to claim 2, wherein
a thickness of the plurality of film-shaped heaters of the second heater layer is larger than a thickness of the plurality of film-shaped heaters of the first heater layer.
